(19) United States
(12) Patent Application Publication
(10) Pub. No.: US 2014/0051197 A1
(43) Pub. Date: Feb. 20, 2014

(54) METHOD FOR FABRICATING A VERTICAL LIGHT EMITTING DIODE (VLED) DIE HAVING EPITAXIAL STRUCTURE WITH PROTECTIVE LAYER

(71) Applicant: SemiLEDS Optoelectronics Co., Ltd., Chu-Nan (TW)

(72) Inventors: FENG-HSU FAN, Jhonghe City (TW); Trung Tri Doan, Baoshan Township (TW); Chuong Anh Tran, Baoshan Township (TW); Chen-Fu Chu, Hsinchu City (TW); Chao-Chen Cheng, Hsinchu City (TW); Jiunn-Yi Chu, Chuebi City (TW); Wen-Huang Liu, Guan-Xi Town (TW); Hao-Chun Cheng, Donggang Township (TW); Jui-Kang Yen, Taipei City (TW)

(73) Assignee: SemiLEDS Optoelectronics Co., Ltd., Chu-Nan (TW)

(21) Appl. No.: 14/064,268

(22) Filed: Oct. 28, 2013

Related U.S. Application Data
(63) Continuation of application No. 13/648,145, filed on Oct. 9, 2012.
Application No. 13/648,145 is a division of application No. 13/310,552, filed on Dec. 2, 2011, now abandoned.
Application No. 13/310,552 is a division of application No. 11/548,642, filed on Oct. 11, 2006, now abandoned.

(51) Int. Cl. H01L 33/00

(52) U.S. Cl. CPC H01L 33/0079
USPC 438/29

(57) ABSTRACT

A method for fabricating a vertical light emitting diode (VLED) die includes the steps of: providing a substrate; forming an epitaxial structure on the substrate; forming an electrically insulative insulation layer covering the lateral surfaces of the epitaxial structure; forming an electrically non-conductive material on the electrically insulative insulation layer; and forming a mirror on the p-doped layer, with the electrically insulative insulation layer configured to protect the epitaxial structure during formation of the mirror.

### CROSS-REFERENCE TO RELATED APPLICATIONS

This application is a continuation of Ser. No. 13/648,145, filed Oct. 9, 2012; which is a division of Ser. No. 13/310,552, filed Dec. 2, 2011, which is a division Ser. No. 11/548,642, filed Oct. 11, 2006, all of which are incorporated by reference.

### TECHNICAL FIELD

Embodiments of the present invention generally relate to a metal device, such as a light emitting diode (LED), a power device, a laser diode, and a vertical cavity surface emitting device, and methods for fabricating the same.

### BACKGROUND

Microelectronic devices, such as metal devices, are playing an increasingly important role in our daily life. For instance, LEDs have become ubiquitous in many applications, such as mobile phones, appliances, and other electronic devices. Recently, the demand for nitride-based semiconductor materials (e.g., having gallium nitride or GaN) for opto-electronics has increased dramatically for applications ranging from video displays and optical storage to lighting and medical instruments.

Conventional blue LEDs are formed using compound semiconductor materials with nitride, such as GaN, AlGaN, InGaN, and AlInGaN. Most of the semiconductor layers of these light-emitting devices are epitaxially formed on electrically non-conductive sapphire substrates.

### SUMMARY

One embodiment of the invention provides a semiconductor die. The semiconductor die generally includes a metal substrate, an epitaxial structure disposed above the metal substrate, and an electrically non-conductive material substantially covering the lateral surfaces of the epitaxial structure. The epitaxial structure generally includes a p-doped layer coupled to the metal substrate and an n-doped layer disposed above the p-doped layer.

Another embodiment of the invention provides a vertical light-emitting diode (VLED) die. The VLED die generally includes a metal substrate, an epitaxial structure disposed above the metal substrate, and an electrically non-conductive material surrounding the epitaxial structure except for the upper surface of the n-GaN layer and a portion of the p-GaN layer coupled to the metal substrate. The epitaxial structure generally includes a p-GaN layer coupled to the metal substrate, a multiple well quantum (MQW) layer for emitting light coupled to the p-doped layer, and an n-GaN layer coupled to the MQW layer.

Yet another embodiment of the invention provides a semiconductor die. The semiconductor die generally includes a metal substrate, a p-doped layer coupled to the metal substrate, a multiple quantum well (MQW) layer disposed above the p-doped layer, an n-doped layer disposed above the MQW layer, and an electrically non-conductive material substantially covering at least the lateral surfaces of the MQW layer.

Yet another embodiment of the invention provides a wafer assembly. The wafer assembly generally includes a substrate, a plurality of epitaxial structures disposed on the substrate, and an electrically non-conductive material substantially covering the lateral surfaces of each of the plurality of epitaxial structures. Each of the epitaxial structures generally includes an n-doped layer coupled to the substrate and a p-doped layer disposed above the n-doped layer.

Yet another embodiment of the invention is a method. The method generally includes providing a wafer assembly comprising a plurality of semiconductor dies formed on a carrier substrate, the dies separated by street areas formed between the dies and having an n-doped layer coupled to the carrier substrate and a p-doped layer disposed above the n-doped layer; filling in at least a portion of the street areas with an electrically non-conductive material; and forming a metal plate above the plurality of semiconductor dies such that the non-conductive material sustains the metal plate, at least during formation, at or above the maximum height of the p-doped layer for the plurality of semiconductor dies.

Yet another embodiment of the invention comprises a method. The method generally includes providing a wafer assembly comprising a plurality of VLED dies formed on a carrier substrate, the VLED dies separated by street areas formed between the dies and having an n-doped layer coupled to the carrier substrate, a multiple quantum well (MQW) layer for emitting light disposed above the n-doped layer, and a p-doped layer disposed above the MQW layer; filling in at least a portion of the street areas with an electrically non-conductive material; and forming a metal plate above the plurality of VLED dies such that the non-conductive material sustains the metal plate, at least during formation, at or above the maximum height of the p-doped layer for the plurality of VLED dies.

### BRIEF DESCRIPTION OF THE DRAWINGS

FIG. 1 is a cross-sectional schematic representation of a wafer illustrating the layers of an epitaxial structure deposited on a carrier substrate in accordance with an embodiment of the invention.

FIG. 2 illustrates defined devices with street areas between devices in accordance with an embodiment of the invention.

FIG. 3 illustrates a semiconductor die 300 having a mirror on the epitaxial structure of FIG. 2 in accordance with embodiments of the invention.

FIGS. 4a-d illustrate semiconductor dice 400a, 400b, 400c, 400d adding electrically non-conductive material to the wafer of FIG. 3b in accordance with embodiments of the invention.

FIGS. 5a-c illustrate semiconductor dice 500a, 500b, 500c, 500d having options for the non-conductive material and an insulative layer in accordance with embodiments of the invention.

FIGS. 6a-c illustrate semiconductor dice 600a, 600b, 600c having options for the mirror, the insulative layer, and the non-conductive material in accordance with embodiments of the invention.

FIG. 7 illustrates a semiconductor die 700 formed by depositing a seed metal, one or more additional metal layers, and a conductive protection layer in accordance with an embodiment of the invention.

FIGS. 8a-b illustrate semiconductor dice 800a, 800b formed by removal of the carrier substrate from the wafer assembly in accordance with embodiments of the invention.

FIG. 9 illustrates a semiconductor die 900 formed by filling in portions of a mesa with metal in accordance with an embodiment of the invention.

FIG. 10 is a flowchart of a method for fabricating vertical light-emitting diode (VLED) dice in accordance with an embodiment of the invention.

### DETAILED DESCRIPTION

Embodiments of the invention provide improvements in the art of light-emitting diodes (LEDs) and methods of fabrication, including higher yield and better performance such as higher brightness of the LED and better thermal conductivity. Moreover, the invention discloses improvements in the fabrication arts that are applicable to GaN-based electronic devices such as vertical light-emitting diode (VLED) devices, power devices, laser diodes, and vertical cavity surface emitting laser devices in cases where there is a high heat dissipation rate of the metal devices that have an original non- (or low) thermally conductivity and/or non- (or low) electrically conductive substrate that has been removed.

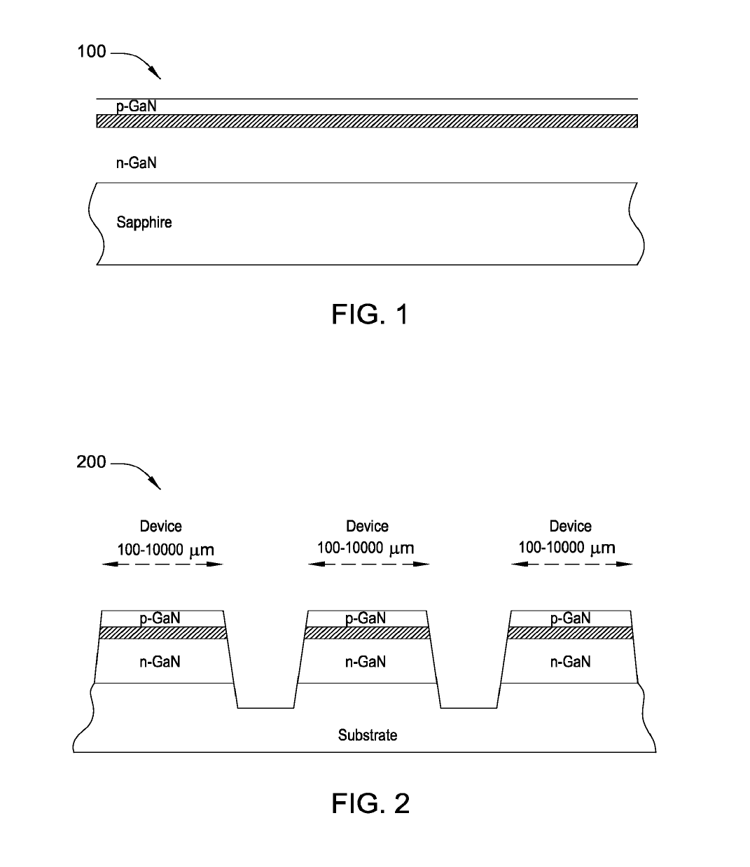

Referring to FIG. 1, a wafer 100 may comprise a carrier substrate. Although the carrier substrate may be composed of sapphire, silicon carbide (SiC), silicon, germanium, zinc oxide (ZnO), or gallium arsenide (GaAs), the examples provided herein will be directed to a carrier substrate that is composed of sapphire. A multilayer epitaxial structure (EPI) may be formed to have an n-type GaN layer, one or more quantum wells with InGaN/GaN layers, and a p-type AIGaN/GaN layer. Although the n-type layer and the p-type layer may comprise various compound semiconductor materials, such as GaN, AlGaN, InGaN, and AlInGaN, n-GaN and p-GaN layers will be described henceforth.

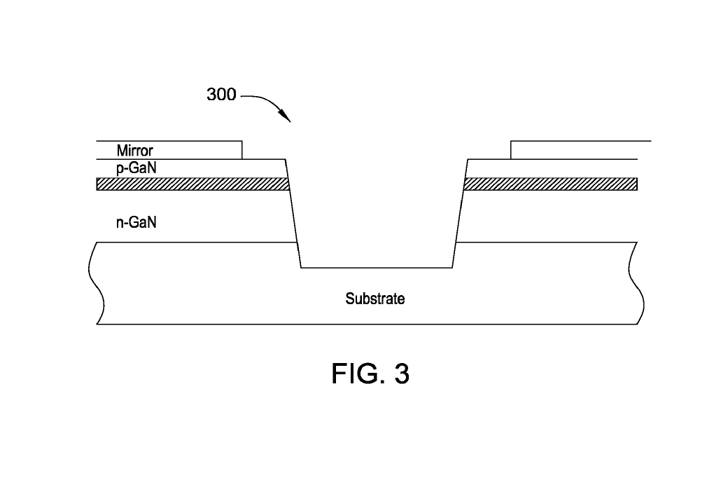

Referring now to FIG. 2, various methods may be used to define one or more devices using a process that cuts directly through a p-n junction and potentially into the carrier substrate, as is shown at 200. These methods are known to those skilled in the art and will not be described herein.

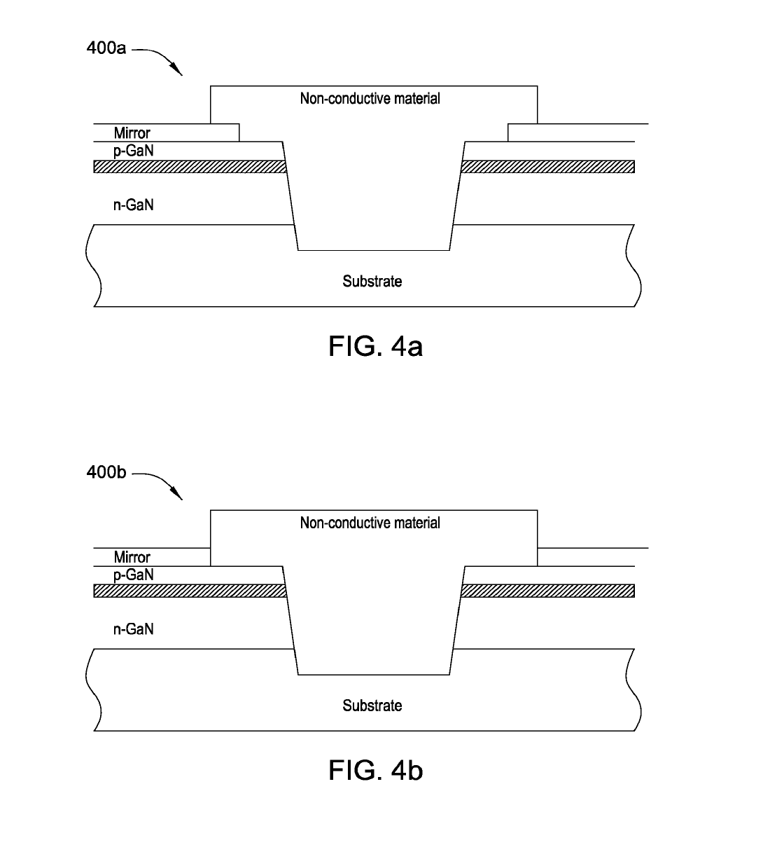

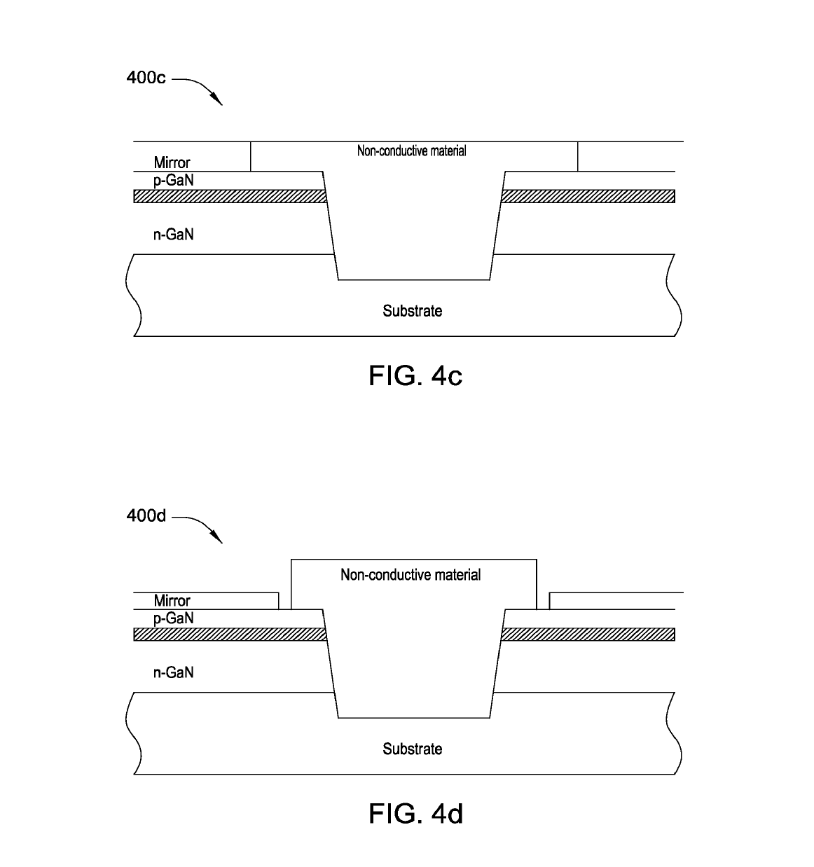

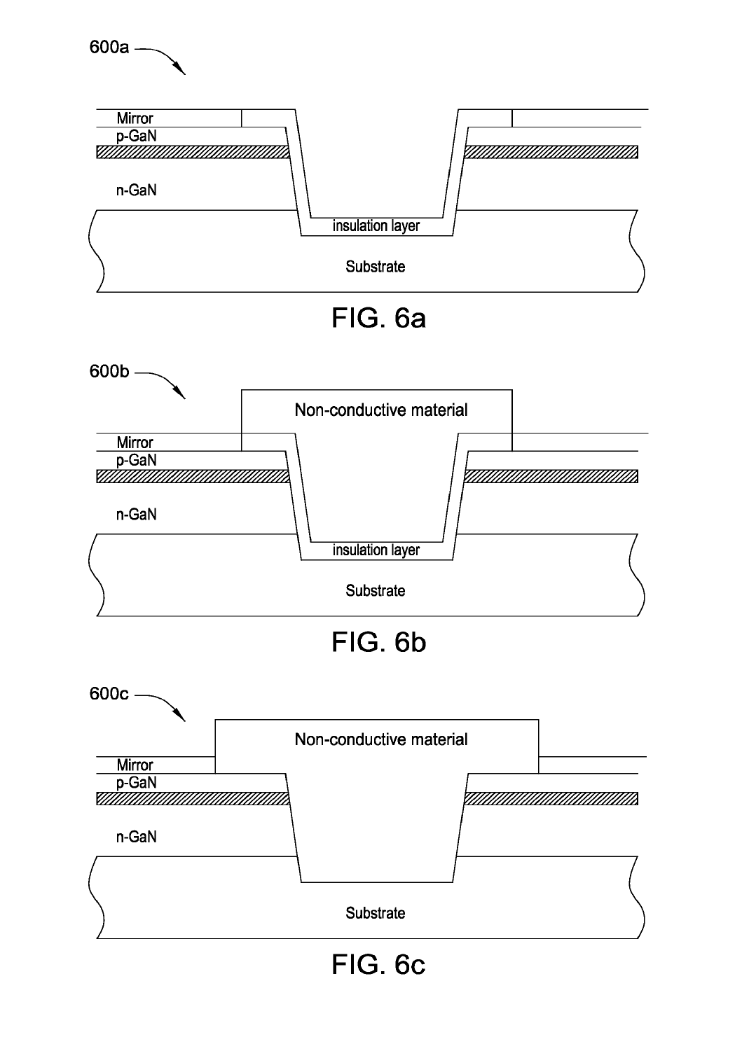

Referring now to FIGS. 3, 4a-d, 5a-c, and 6a-c, a mirror may be formed on top of the p-GaN to act as the reflector for photons. The mirror, by way of example, may be composed of multiple layers, such as Ni/Ag/Ni/Au, Ag/Ni/Au, Ti/Ag/Ni/Au, Ag/Pt or Ag/Pd or Ag/Cr, using an alloy containing Ag, Au, Cr, Pt, Pd, or AI. Optionally, the mirror may be formed after an insulation layer is formed, as shown in FIGS. 6a-b, in an effort to protect the junction areas. In such cases, the mirror may be formed after portions of the insulation layer have been removed from unwanted areas. FIGS. 3, 4a-d, and 6a-c show a variety of different ways to form the mirror on the epitaxial wafer assembly.

One or more electrically insulative layers, which may also be thermally conductive layers, (hereinafter referred to as the “insulation layer”), may be formed on top of the junction to protect the junction, after which portions of the insulation layer may be removed from unwanted areas. For some embodiments, as shown in FIGS. 6a-b, the mirror and the insulation layer may be defined by (i) depositing the insulation layer; (ii) forming a masking layer; (iii) using a wet or dry etch to remove a portion of the insulation layer that is on top of the p-GaN layer; (iv) depositing the mirror; and (v) then lifting off the masking layer so as to leave the mirror on top of the exposed p-GaN.

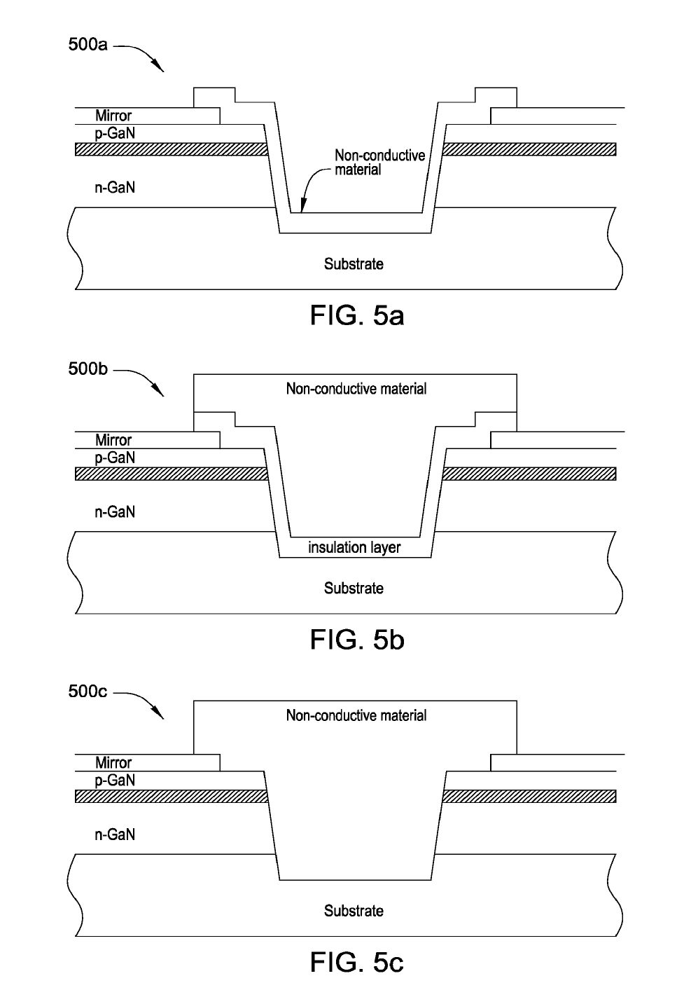

One or more electrically non-conductive layers, which may also be thermally conductive layers, (hereinafter referred to as the “non-conductive material”) may be used to fill the street, the area between the defined devices, and cover at least a portion of the lateral surfaces of the epitaxial structure. The lateral surfaces may be defined as the side surfaces (e.g., non-horizontal surfaces) of the various layers of the epitaxial structure along the trench. The filling of the streets with the non-conductive material may advantageously reduce, absorb, or perhaps stop the interaction of a potentially destructive force (e.g., ultraviolet (UV) light absorption or a laser induced shock wave) that might otherwise damage electrical devices during the separation of the epitaxial wafer assembly. By way of example, the non-conductive material that is used to fill the streets may be an organic material, such as an epoxy, a polymer, a polyimide, thermoplastic, and sol-gel. A photo sensitive organic material, such as SU-8, NR-7, or AZ5214E may also be employed so that one does not have to define the material using a mask. The non-conductive material may also comprise inorganic materials such as SiO2, ZnO, Ta2O5, TiO2, HfO, or MgO. The non-conductive material that fills in the street will also cover the p-GaN as a layer that will further protect the active area, if the insulation layer does not remain over the active area (see FIGS. 5a-c). The non-conductive material may be either above or co-planar with the mirror, which may be multiple layers.

For some embodiments, the insulation layer may be used alone or in conjunction with the non-conductive material. Alternatively, the non-conductive material may be used by itself as seen in FIG. 5c where the insulation layer is not present. Referring to FIG. 5a, moreover, the non-conductive material may not completely fill in the trench for some embodiments. In such cases, the p-GaN may or may not be covered, but at least the MQW layer should be covered by either the non-conductive material or the insulation layer in embodiments where either is employed.

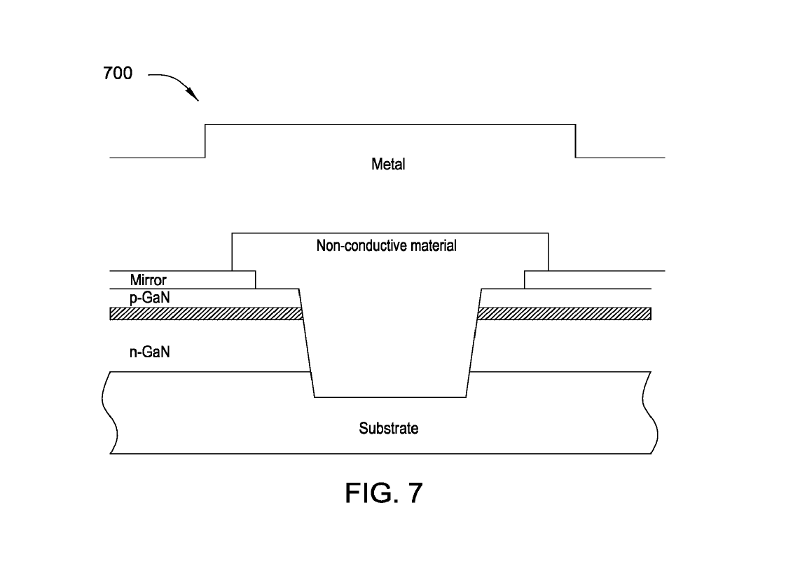

A deposition of one or more metal layers may be made on top of the mirror and the non-conductive material in an effort to create one thick metal plate, for instance, as seen as “metal” in FIG. 7. The metal layer may be single or multi-layered. In cases where the metal layer is a multi-layered structure, a plurality of metal layers with different composition (e.g., Cu, Ni, Ag, Au, Co, Cu—Co, Cu—Mo, Ni/Cu, Ni/Cu—Mo, and their alloys) may be formed, where these layers may be formed using different techniques. The thickness of each metal layer may be about 10˜400 μm.

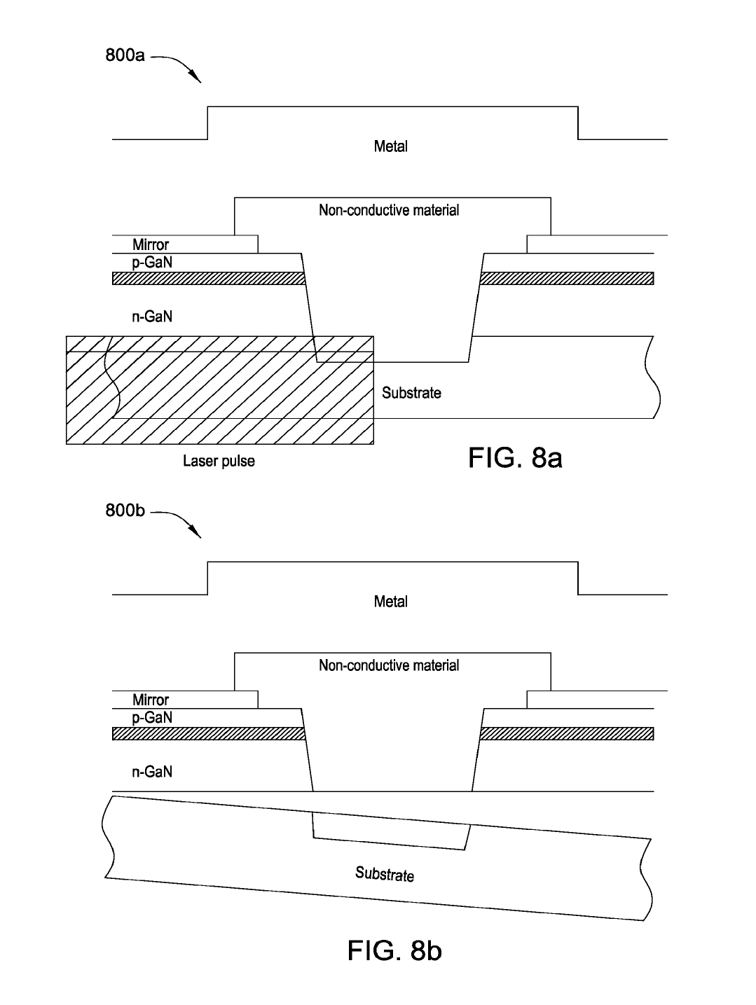

Using various techniques, preferably by a laser operation, the electrical devices fabricated on the epitaxial wafer assembly may be separated from the substrate, as shown in FIGS. 8a-b. This separation may be accomplished by various processes, such as pulse laser irradiation, selected photo enhancement chemical etching of the interfacial layer between the substrate and the GaN, wet etching of the substrate, or lapping/polishing with chemical mechanical polishing.

For some embodiments, the electrical devices fabricated on the epitaxial wafer assembly may be separated from the substrate, as shown in FIG. 8a, using a pulse laser irradiation operation. Such devices may be fabricated in an effort to prevent damage (e.g., cracking) to GaN devices during the separation. Pulse laser irradiation may be used to decompose the interfacial layer of GaN on the substrate and/or remove the electrical devices from the substrate, although the electrical devices may still be held in place where the epitaxial wafer assembly has not been completely removed from the substrate.

The separation of the GaN using pulse laser irradiation may result in its decomposition into Ga and N2, where the ablation of GaN only takes a few nanoseconds in an effort to avoid an explosion with N2 plasma. The light absorption and shock wave generated by the pulse laser irradiation from two laser beams may overlap the street region. As seen in FIG. 8a, the shaded region, which is meant to represent a laser pulse, may partially overlap the substrate such that the laser operation extends all the way into the street.

For some embodiments, the non-conductive material may advantageously reduce, absorb, or stop an interaction of a force (e.g., UV light absorption or a laser induced shock wave) that would otherwise potentially damage adjacent electrical devices during the separation of the devices from the substrate as described herein in relation to FIG. 8a. Upon removal of the substrate in some instances, a portion of the non-conductive material may overlap the newly exposed surface of the n-GaN, although this overlap is not typically desired. For some embodiments, however, additional non-conductive material may be added to cover at least a portion of the newly exposed n-GaN surface.

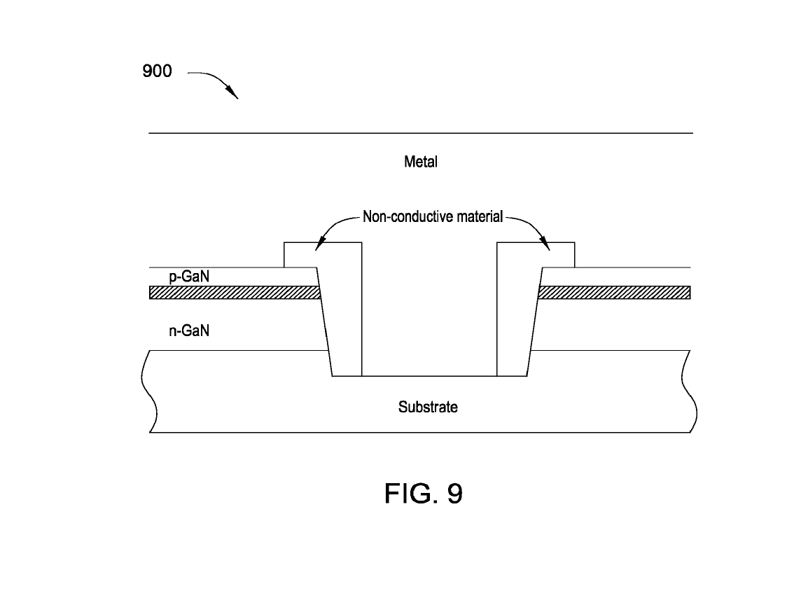

The non-conductive material, which in some embodiments may simply make contact with the substrate rather than penetrate the substrate as shown in FIG. 9, may be chosen as photo-sensitive or non-photo-sensitive material (e.g., polymer, polyimide, SU-8, NR-7, AZ5214E, thermoplastic, ZnO, Ta2O5, TiO2, HfO, or MgO).

After separating the substrate from the epitaxial wafer assembly, the wafer may be diced (i.e., dicing into individual semiconductor dies) using any combination of various suitable techniques. Semiconductor dicing techniques are known to those skilled in the art and will not be described herein.

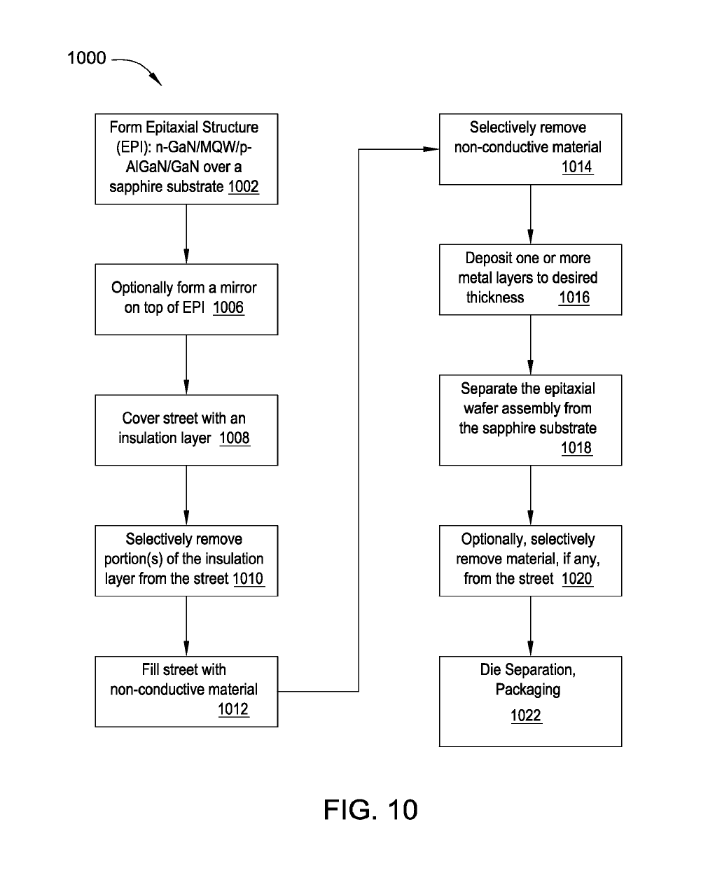

FIG. 10 depicts a process 1000 that is an exemplary implementation for fabricating a VLED. Note that the process 1000 is only an example of one implementation of such a process, that the steps seen in process 1000 may be re-arranged, and that some of the steps may be optional. Process 1000 includes a step 1002 of providing a sapphire substrate and forming an epitaxial structure over the sapphire substrate, where the epitaxial structure may comprise n-GaN/MQW/p-AIGaN/GaN. Optionally, at step 1006, a mirror may be formed on top of the p-GaN. At step 1008, at least portions of the streets may be covered with an insulation layer. As a further option, steps 1006 and 1008 may be reversed. At step 1010, portions of the insulation layer from a street may be selectively removed, and the street may be filled with a non-conductive material in step 1012. The non-conductive material may be selectively removed in step 1014, followed in step 1016 by the growing of one or more metal layers to a desired thickness. In step 1018, the epitaxial structure may be separated from the sapphire substrate. As a further option, in step 1020, material may be selectively removed from the street, and a dicing operation may take place in step 1022. The dicing operation may use any suitable technique. After each die has been separated, packaging and assembly of each die may be performed.

Embodiments disclosed herein may also be applied to the fabrication of GaN-based electronic devices such as power devices, laser diodes, and vertical cavity surface emitting laser device due to its high heat dissipation rate of its metal substrate. Relative to LEDs, the above teaching can improve yield, brightness, and thermal conductivity.

While the foregoing is directed to embodiments of the present invention, other and further embodiments of the invention may be devised without departing from the basic scope thereof, and the scope thereof is determined by the claims that follow.

We claim:

1. A method for fabricating a vertical light emitting diode (VLED) die comprising:
providing a substrate;
forming an epitaxial structure on the substrate comprising:
a p-doped layer coupled to the substrate;
an n-doped layer on the substrate; and
a multiple quantum well layer between the p-doped layer and the n-doped layer configured to emit light,
the p-doped layer, the n-doped layer and the multiple quantum well layer forming lateral surfaces of the epitaxial structure;
forming an electrically insulative insulation layer covering the lateral surfaces of the epitaxial structure and a portion of the p-doped layer;
forming an electrically non-conductive material on the electrically insulative insulation layer; and
forming a mirror on the p-doped layer, the electrically insulative insulation layer configured to protect the epitaxial structure during forming of the mirror.

2. The method of claim 1 further comprising forming a metal on the electrically non-conductive material.

3. The method of claim 1 further comprising separating the substrate from the epitaxial structure.

4. The method of claim 1 wherein the electrically non-conductive material comprises an organic photosensitive material.

5. The method of claim 1 wherein the electrically insulative insulation material covers a portion of the substrate.

6. The method of claim 1 wherein the substrate comprises a material selected from the group consisting of Cu, Ni, Au, Ag and Co.

7. The method of claim 1 wherein the mirror comprises a material selected from the group consisting of Ag, Au Cr, Pt, Pd, Al, Ni/Ag/Ni/Au, Ag/Ni/Au, Ti/Ag/Ni/Au, Ag/Pt, Ag/Pd and Ag/Cr.

8. A method for fabricating a vertical light emitting diode (VLED) die comprising:
providing a substrate;
forming an epitaxial structure on the substrate comprising:
a p-doped layer coupled to the substrate;
an n-doped layer on the substrate; and
a multiple quantum well layer between the p-doped layer and the n-doped layer configured to emit light;
defining a plurality of dice on the substrate by forming trenches through the epitaxial structure such that the p-doped layer, the n-doped layer and the multiple quantum well layer form lateral surfaces of the dice;
forming an electrically insulative insulation layer covering the lateral surfaces of the dice and a portion of the p-doped layer;
forming an electrically non-conductive material on the electrically insulative insulation layer;
forming a mirror on the p-doped layer, with the electrically insulative insulation layer configured to protect the epitaxial structure during forming of the mirror;
forming a metal on the electrically non-conductive material and on the mirror;
separating the substrate from the epitaxial structure; and
separating the dice.

9. The method of claim 8 wherein the substrate comprises a wafer.

10. The method of claim 8 wherein the electrically non-conductive material comprises an organic photosensitive material.

11. The method of claim 8 wherein the electrically insulative insulation material covers a portion of the substrate.

12. The method of claim 8 wherein the substrate comprises a material selected from the group consisting of Cu, Ni, Au, Ag and Co.

13. The method of claim 1 wherein the mirror comprises a material selected from the group consisting of Ag, Au Cr, Pt, Pd, Al, Ni/Ag/Ni/Au, Ag/Ni/Au, Ti/Ag/Ni/Au, Ag/Pt, Ag/Pd and Ag/Cr.

14. The method of claim 1 wherein the substrate comprises sapphire.
